(19) United States
(12) Patent Application Publication
(10) Pub. No.: US 2011/0109970 A1
(43) Pub. Date: May 12, 2011

(54) FILM TYPE LIGHT SHADING PLATE, AND DIAPHRAGM, DIAPHRAGM DEVICE FOR ADJUSTING A LIGHT INTENSITY OR SHUTTER USING THE SAME

(75) Inventors: Yoshiyuki Abe, Chiba (JP); Katsushi Ono, Chiba (JP); Yukio Tsukakoshi, Chiba (JP)

(73) Assignee: SUMITOMO METAL MINING CO., LTD., Tokyo (JP)

(21) Appl. No.: 12/997,762

(22) PCT Filed: Apr. 27, 2009
(86) PCT No.: PCT/JP2009/058264

§ 371 Date: Dec. 13, 2010

(30) Foreign Application Priority Data
Jun. 27, 2008 (JP) 2008-168995

(51) Int. Cl. G02B 27/00; C23C 14/08; B32B 9/00; B32B 27/06

(52) U.S. Cl. 359/601; 428/332; 428/336; 428/213; 428/141; 204/192.27

(57) ABSTRACT

The film type light shading plate widely applicable to optical parts in which a light shading thin film having sufficient light shading performance and low reflectivity in the visible range is formed on a resin film of a base substrate, and further a diaphragm for digital camera or digital video camera, a diaphragm device for adjusting a light intensity of projector or a shutter to which said film type light shading plate is applied. The film type light shading plate in which a light shading thin film (B) comprising of a crystalline titanium oxy-carbide film is formed on at least one surface of the resin film substrate (A), characterized in that the light shading thin film (B) has an average optical density of 4.0 or more in wavelength 400 to 800 nm by a carbon content of 0.6 or more as C/Ti atomicity ratio, an oxygen content of 0.2 to 0.6 as O/Ti atomicity ratio, and a total thickness of the light shading thin film (B) of 260 nm or more.

### BACKGROUND OF THE INVENTION

1. Field of the Invention

The present invention relates to a film type light shading plate, and diaphragm, diaphragm device for adjusting a light intensity or shutter using the same. In more detail, the present invention relates to a film type light shading plate widely applicable to optical members in which a light shading thin film having sufficient light shading performance and low reflectivity in the visible wavelength range is formed on a resin film of a base substrate, and further, a diaphragm for digital camera or digital video camera, a diaphragm device for adjusting a light intensity for projector or a shutter to which said film type light shading plate is applied.

2. Description of the Prior Art

In recent years, in the digital camera industry, development of a high speed (mechanical) shutter has been actively promoted. Purpose of this high speed shutter is to obtain clear images by taking a picture of a subject moving at an ultrahigh speed without blurring by making shutter speed high. Generally, opening/closing of shutter is performed by rotating or moving a plurality of blades called as shutter blades. In order to obtain a high shutter speed, weight saving and high slidability are absolutely essential so that motion and stopping of shutter blade can be done in an extremely short time. Further, since shutter blade serves to shade light by covering the front surface of a photosensitive material such as film or an image sensor such as CCD, CMOS in a state when a shutter is closed, it is desired to have not only a complete light shading performance but also a low light reflectance on the surface of the blade, that is, a high blackness, in order to prevent an occurrence of leakage of light among each blade when a plurality of shutter blades work while overlapping each other.

As for fixed diaphragm which is inserted into a lens unit of digital camera and has a role to reduce light intensity to a certain level and transfer the light to an image sensor, it is also demanded to have a low reflectance on the surface, that is, a high blackness, because occurrence of light reflection on the surface of diaphragm gives stray light and impairs sharp images.

Also, in cellar phone having a photographing function, that is, cellar camera phone, a compact mechanical shutter has recently begun to be installed in a lens unit in order to allow taking a picture having fine pixel and high image quality. In addition, a fixed diaphragm has been inserted in a lens unit. In the case of mechanical shutter to be incorporated in a cellar phone, demand for weight saving of shutter blades has become particularly intense because operation by power saving is required.

Furthermore, in assembly of a lens unit in recent cellar phone, assembly of each part such as lens, fixed diaphragm, shutter has been required to be carried out in a reflow process, for the purpose to reduce production cost. The shutter blades and fixed diaphragm to be used in such process are required to have not only low reflectance and blackness of the surface but also heat resistance. The heat resistance required for the shutter blades and fixed diaphragm, which can be used in the reflow process, is around 270° C.

Next, concerning in-vehicle monitors, a case in which a back-view monitor or the like is mounted has become popular as a recent trend. In a lens unit of this monitor, a fixed diaphragm is also used, which is similarly required to have a low reflectance and blackness of the surface to avoid stray light. In a lens unit being used in the in-vehicle monitor, a fixed diaphragm member is also required to have heat resistance not to impair the function even in a use environment at such a high temperature as under the scorching sun in midsummer. It is generally believed that the fixed diaphragm member to be used for in-vehicle monitor or the like is required to have a heat resistance of around 120° C.

On the contrary, a liquid crystal projector has recently been rapidly becoming popular at home because it makes enjoying images possible as a home theater with a large-sized screen in a big room. Since high image quality is intensely demanded in order to enjoy sharp high contrast images even in such a bright environment as in a living room, a technology to obtain an image quality having high brightness by using high power light source has been progressed. In an optical system of the liquid crystal projector, a diaphragm device for adjusting a light intensity (auto-iris), which adjusts light intensity from a light source, has been used inside or on side face of the lens system. In the diaphragm device for adjusting a light intensity, a plurality of diaphragm blades overlaps each other in the same way as in the shutter to adjust an area of opening through which light passes. In such diaphragm blades of diaphragm device for adjusting a light intensity, low reflectance on the surface and weight saving are also required due to the same reasons as in the case of shutter blades. Namely, if low reflectance of blade material deteriorates by light irradiation, stray light is generated and sharp images can be hardly projected. In addition, at the same time, heat resistance against heating by irradiation of lamp light has been also required. It is believed that a diaphragm blade material of the diaphragm device for adjusting a light intensity for liquid crystal projector generally requires a heat resistance up to around 270° C.

As a light shading plate using for the above-described shutter blade, fixed diaphragm material, and diaphragm blade of diaphragm device for adjusting a light intensity, the follows are generally used.

Namely, for light shading plate in which heat resistance is required, a thin plate of metal such as SUS, SK material, Al, Ti is generally used as a substrate. Although there is a light shading plate in which metal thin plate itself is used as a light shading plate, this is not preferable when influence of stray light by reflected light from the surface should be avoided because this plate has metallic luster. On the contrary, a light shading plate in which a black lubricating film is coated on a metal thin plate has low reflectance and blackness, but cannot generally be used in a high temperature environment because a coated part is inferior in heat resistance.

In Patent Literature 1, a light shading member in which a hard carbon film has been formed on the surface of blade member made of a metal such as aluminum based alloy has been proposed. However, even if a hard carbon film is formed on the surface of metal blade member, sufficient low reflectivity cannot be realized, and generation of stray light by reflected light cannot be avoided. In addition, when a light shading plate used a metal thin plate as a substrate is used for shutter blade or diaphragm blade, there are such problems that torque of driving motor, which drives blades, becomes great to increase electric power consumption due to its heavy weight; shutter speed cannot be increased; noise is generated by contacting of blades with each other; and the like. On the contrary, there is a light shading plate used a resin film as a substrate, and in Patent Literature 2, a film type light shading plate used a mat finished resin film to reduce reflection on the surface or provided lusterless finish by forming a large number of fine irregularities on the surface have been proposed.

In addition, in Patent Literature 3, a light shading film in which a thermosetting resin containing a lusterless paint is coated on a resin film has been proposed. However, these are nothing more than reducing the reflection on the surface by finishing of film itself or addition of a delusterant, and influence of stray light by reflection from the light shading blades can be hardly prevented.

Concerning resin film substrate, many light shading films use polyethylene terephthalate (PET) as a substrate from the viewpoints of low specific gravity, cheap cost and flexibility. In addition, a PET film, which has a decreased transmittance by impregnating therein black colored fine particles such as carbon black, titanium black, is widely used. However, PET material has a heat resistance below 150° C. and poor mechanical strength such as tensile modulus of elasticity. Consequently, when the PET material is used for a member of diaphragm for adjusting a light intensity of projector, which is used under irradiation of light from a high power lamp, or a member of fixed diaphragm or shutter for corresponding to the reflow process, the PET material cannot be utilized because of its inferior heat resistance. In addition, as a member of high speed shutter blade, thickness of the film has to be reduced corresponding to speeding up of shutter blade, however, in the case of the film obtained by impregnating therein black colored fine particles, its thickness becomes very thin, in particular, when the thickness becomes 38 μm or less, the film cannot be used for shutter blade because the film cannot exhibit sufficient light shading performance in the visible range. Furthermore, since such resin film obtained by impregnating therein black colored fine particles has insulation property, when the resin film is used for shutter blades, the blades rub each other to generate static electricity and cause problems such as adsorbing dust and the like.

For this reason, in Patent Literature 4, a light shading blade material has been proposed, which comprises a film type substrate, a light shading film having a light shading performance formed on the one or both surfaces thereof, and a protective film formed thereon, and can satisfy one or more properties of electrical conductivity, lubricating property and abrasion resistance by this protective film. The above-described substrate comprises a resin material tolerable at a processing temperature of at least 150° C., and the above-described light shading film is constituted of a thin film containing a metal deposited by vacuum deposition process, sputtering process or plasma CVD process in which processing temperature of 150° C. or lower can be maintained. However, nothing about low reflectance and blackness, each of which is one of requirements for light shading blade, has been referred to, and only a light shading blade member using carbon as a protective film has been specifically shown, in which effect of the carbon on abrasion resistance has been confirmed.

As mentioned above, a light shading plate applicable to shutter blade, fixed diaphragm and diaphragm blade of diaphragm device for adjusting a light intensity etc. which has sufficient light shading performance and low reflectivity in the visible range, lightweight character, and electrical conductivity all together has not been known until now. In particular, in a film type light shading plate used a resin film substrate, which is advantageous for lightweight character, a light shading plate, which has complete light shading performance even with a plate thickness of 38 μm or less, has not been known. In addition, even when each part is assembled in the reflow process, a film type light shading plate base on a resin film substrate, which has heat resistance at 270° C. without deteriorating in quality in the reflow process, has not been found.

Under such circumstances, shutter blades, fixed diaphragm and diaphragm blades of diaphragm device for adjusting a light intensity comprising of a film type light shading plate used a thin resin film substrate which is advantageous for lightweight character, and having sufficient light shading performance and low reflectance in the visible range, lightweight character, and electrical conductivity all together, which can be assembled from each part in a reflow process, have been demanded.
Patent Literature 1: JP-A-2-116837:
Patent Literature 2: JP-A-1-120503;
Patent Literature 3: JP-A-4-9802;
Patent Literature 4: JP-A-2006-138974.

### SUMMARY OF THE INVENTION

Considering these conventional problems, an object of the present invention is to provide a film type light shading plate widely applicable to optical members in which a light shading thin film having sufficient light shading performance and low reflectance in the visible range is formed on a resin film of a base substrate, and further, diaphragm for digital camera or digital video camera, diaphragm device for adjusting a light intensity for projector, or shutter to which said film type light shading plate is applied.

In order to solve the above-described problem, the present inventors have intensively searched for light shading film, which has complete light shading performance and low reflectance in the visible range (wavelength 400 to 800 nm) and superior adhesion to a resin film substrate. As a result, the inventors have found that a film type light shading plate having sufficient light shading performance and low reflectance together in the visible range, as well as high adhesion to a resin film substrate and heat resistance at 270° C. can be obtained by forming a crystalline film of titanium oxy-carbide having a carbon content and an oxygen content in the thin film in specified ranges on a resin film substrate by sputtering using a titanium oxy-carbide sintered body target having specified carbon content and oxygen content, and using this film as a light shading thin film, and also found that this film type light shading plate not only exhibits complete light shading performance, low reflectance and electrical conductivity, but also can be utilized as a shutter blade material of high speed shutter, which can correspond to low power driving due to lightweight character, and also can contribute to miniaturization of driving motor, and also realize miniaturization of diaphragm device for adjusting a light intensity and mechanical shutter, and finally completed the present invention.

Namely, according to the first aspect of the present invention, there is provided a film type light shading plate in which a light shading thin film (B) comprising of a crystalline titanium oxy-carbide film is formed on at least one surface of the resin film substrate (A), characterized in that the light shading thin film (B) has an average optical density of 4.0 or more in wavelength 400 to 800 nm by having a carbon content of 0.6 or more as C/Ti atomicity ratio, an oxygen content of 0.2 to 0.6 as O/Ti atomicity ratio, and a thickness of the light shading thin film (B) of 260 nm or more in total.

Further, according to the second aspect of the present invention, there is provided the film type light shading plate, characterized in that in the first aspect the light shading thin film (B) has a film thickness of 260 to 500 nm in total.

Further, according to the third aspect of the present invention, there is provided the film type light shading plate, characterized in that in the first aspect the resin film substrate (A) comprises one or more types of resins selected from polyethylene terephthalate (PET), polycarbonate (PC), polyethylene naphthalate (PEN), polyimide (PI), aramid (PA), polyphenylene sulfide (PPS), or polyether sulfone (PES).

Further, according to the fourth aspect of the present invention, there is provided the film type light shading plate, characterized in that in the first aspect the resin film substrate (A) is selected from polyimide (PI), aramid (PA), polyphenylene sulfide (PPS), or polyether sulfone (PES) which have heat resistance at temperature of 200° C. or higher.

Further, according to the fifth aspect of the present invention, there is provided the film type light shading plate, characterized in that in the first aspect a thickness of the resin film substrate (A) is 38 μm or less.

In addition, according to the sixth aspect of the present invention, there is provided the film type light shading plate, characterized in that in the first aspect a thickness of the resin film substrate (A) is 25 μm or less.

On the contrary, according to the seventh aspect of the present invention, there is provided the film type light shading plate, characterized in that in the first aspect the light shading thin film (B) is formed on the both surfaces of the resin film substrate (A) and both of the light shading thin film (B) have substantially the same composition and the same film thickness.

In addition, according to the eighth aspect of the present invention, there is provided the film type light shading plate, characterized in that in the first aspect the surface of the light shading thin film (B) is electrical conductivity.

In addition, according to the ninth aspect of the present invention, there is provided the film type light shading plate, characterized in that in the first aspect the surface of the light shading thin film (B) has a direct reflectance for light of 39% or less in average in wavelength 400 to 800 nm.

In addition, according to the tenth aspect of the present invention, there is provided the film type light shading plate, characterized in that in the first aspect the surface of the light shading thin film (B) has a surface roughness of 0.15 to 0.70 μm (in arithmetic average height).

In addition, according to the eleventh aspect of the present invention, there is provided the film type light shading plate, characterized in that in the ninth aspect the surface of the light shading thin film (B) has a direct reflectance for light of 1.5% or less in average in wavelength 400 to 800 nm.

In addition, according to the twelfth aspect of the present invention, there is provided the film type light shading plate, characterized in that in the tenth aspect the surface of the light shading thin film (B) has a surface roughness of 0.32 to 0.70 μm (in arithmetic average height).

In addition, according to the thirteenth aspect of the present invention, there is provided the film type light shading plate, characterized in that in the eleventh aspect the surface of the light shading thin film (B) has a direct reflectance of 0.8% or less in average in wavelength 400 to 800 nm.

In addition, according to the fourteenth aspect of the present invention, there is provided the film type light shading plate, characterized in that in the first aspect film deposition of the light shading thin film (B) is performed on the surface of the resin film substrate (A) by sputtering process while the resin film substrate (A) is set in a roll type in a film delivery section of a sputtering equipment, then taken up from a wind-off section to a take-up section.

In addition, according to the fifteenth aspect of the present invention, there is provided the film type light shading plate, characterized in that in the first aspect the light shading thin film (B) is formed on the resin film substrate (A) by the sputtering process using a titanium oxy-carbide sintered body target.

In addition, according to the sixteenth aspect of the present invention, there is provided the film type light shading plate, characterized in that in the fifteenth aspect the titanium oxy-carbide sintered body target contains 0.6 or more of carbon in C/Ti atomicity ratio and 0.17 to 0.53 of oxygen in O/Ti atomicity ratio.

In addition, according to the seventeenth aspect of the present invention, there is provided the film type light shading plate, characterized in that in the first aspect surface temperature of the resin film substrate (A) in sputtering is 100° C. or lower.

In addition, according to the eighteenth aspect of the present invention, there is provided the film type light shading plate, characterized in that in the first aspect the light shading plate has a heat resistance in the high temperature environment at 270° C.

In addition, according to the nineteenth aspect of the present invention, there is provided a diaphragm made by processing the film type light shading plate according to any one of the first to the eighteenth aspects.

At the same time, according to the twentieth aspect of the present invention, there is provided a diaphragm device for adjusting a light intensity made by using a blade member obtained by processing the film type light shading plate according to any one of the first to the eighteenth aspects.

Further, according to the twenty-first aspect of the present invention, there is provided a shutter made by using a blade member obtained by processing the film type light shading plate according to anyone of the first to the eighteenth aspects.

The light shading thin film to be used in the present invention is a crystalline titanium oxy-carbide film, which is a thin film having a carbon content of 0.6 or more in C/Ti atomicity ratio and an oxygen content of 0.2 to 0.6 in O/Ti atomicity ratio in the film; has complete light shading performance and low reflectance in the visible range (in wavelength 400 to 800 nm); and is superior in adhesion to the resin film substrate. Moreover, these characteristics are not impaired even in a high temperature environment at 270° C. in the atmosphere.

In addition, the film type light shading plate of the present invention is the one in which the above-described light shading thin film is formed on a resin film as a substrate, and superior in lightweight character compared with a conventional light shading plate which is based on a metal thin plate. In addition, the film type light shading plate of the present invention, which uses a resin film substrate of 38 μm or less for further weight saving, can exhibit complete light shading performance and low reflectance in comparison with a conventional light shading plate in which black colored fine particles are impregnated in a resin film having the same thickness, and can be utilized for shutter blade material of high speed shutter, which can correspond to low power driving, and can also contribute to miniaturization of driving motor. Since the film type light shading plate of the present invention has further such merits that miniaturization of diaphragm device for adjusting a light intensity and mechanical shutter by weight saving can be realized, and the like, it can be considered to be industrially extremely useful.

In addition, the film type light shading plate of the present invention can exhibit heat resistance at 270° C. in the atmosphere by using a heat resistant resin film such as polyimide as a substrate. Namely, since low reflectance and light shading performance are not impaired even in a high temperature environment at 270° C., the film type light shading plate of the present invention can be utilized for a diaphragm blade material of diaphragm device for adjusting a light intensity in a liquid crystal projector and a fixed diaphragm material or a shutter blade material, which can correspond to assembly by the reflow process, and therefore can be considered to be also extremely industrially worthy in this point.

### BRIEF DESCRIPTION OF THE DRAWINGS

FIG. 1 is a schematic diagram showing a cross-section of the film type light shading plate of the present invention in which a light shading thin film was formed on one surface of a resin film.

FIG. 2 is a schematic diagram showing a cross-section of the film type light shading plate of the present invention in which light shading thin films were formed on both surfaces of a resin film.

FIG. 3 is a schematic diagram of a take-up roll sputtering equipment for producing the film type light shading plate of the present invention.

FIG. 4 is a pattern diagram showing diaphragm mechanism of a diaphragm device for adjusting a light intensity mounted with black colored light shading blade which was manufactured by punching out the film type light shading plate of the present invention.

FIG. 5 is a chart showing the results of X-ray diffraction pattern measurement on the titanium oxy-carbide film obtained according to the present invention (Example 1).

FIG. 6 is a chart showing the results of X-ray diffraction pattern measurement on the titanium oxy-carbide film obtained under the conditions of Comparative Example.

### NOTATION

0: Film type light shading plate
1: Resin film
2: Light shading thin film
5: Wind-off roll
6: Vacuum pump
7: Vacuum chamber
8: Cooling can roll
9: Take-up roll
10: Magnetron cathode
11: Target
12: Partition wall
14: Heat resistant light shading blade
15: Guide hole
16: Guide pin
17: Pin
18: Substrate
19: Hole
20: Opening

### DETAILED DESCRIPTION OF THE INVENTION

Hereinafter, the film type light shading plate of the present invention, and diaphragm, diaphragm device for adjusting a light intensity or shutter used the same will be explained.

### 1. Film Type Light Shading Plate

The film type light shading plate of the present invention is a film type light shading plate in which a light shading thin film (B) comprising of a crystalline titanium oxy-carbide film is formed on at least one surface of the resin film substrate (A), characterized in that the light shading thin film (B) has a carbon content of 0.6 or more as C/Ti atomicity ratio; an oxygen content of 0.2 to 0.6 as O/Ti atomicity ratio; a film thickness of 260 nm or more in total; and an average optical density of 4.0 or more in wavelength 400 to 800 nm.

### (A) Resin Film Substrate

As the resin film, for example, a film composed of one or more types of materials selected from polyethylene terephthalate (PET), polycarbonate (PC), polyethylene naphthalate (PEN), polyimide (PI), aramid (PA), polyphenylene sulfide (PPS), or polyether sulfone (PES), a film in which acryl hard coating is applied on the surface of these resin films, and a film in which black colored fine particles such as carbon black, titanium black are impregnated in these resin films to reduce transmittance can be utilized.

In order to realize a film type light shading plate, which is lightweight and usable even in an environment at high temperature, it is preferable to use a substrate based on a heat resistant resin film. When a heat resistance up to around 120 to 150° C. is imparted, polyethylene naphthalate (PEN) is effective. Fixed diaphragm member to be used for in-vehicle monitor requires heat resistance up to around 120° C., and therefore this can be realized by using polyethylene naphthalate.

When a heat resistance up to 200° C. or higher is imparted, a film composed of one or more types of heat resistant materials selected from polyimide (PI), aramid (PA), polyphenylene sulfide (PPS), or polyether sulfone (PES) is preferable. Among them, polyimide film is particularly preferable because it has the highest heat resistant temperature of 270° C. or higher. In order to obtain a film type light shading plate utilizable for fixed diaphragm member and shutter blade material, which can correspond to assembly by the reflow process, use of polyimide film is effective.

Thickness of the resin film substrate is preferably 200 μm or less, more preferably 100 μm or less, and most preferably 50 μm or less. The resin film substrate thicker than 200 μm is not preferable and could be improper for certain applications, because it becomes difficult to mount a plurality of light shading blades on a diaphragm device and a device for adjusting a light intensity in which miniaturization is progressing.

In addition, when the film type light shading plate is utilized as a fixed diaphragm of lens unit, light reflection in the facet of a diaphragm in a light path becomes stray light, which can be a factor to disturb taking a picture of clear image quality. In order to reduce the light reflection in the facet of a diaphragm as much as possible, it is effective to reduce a thickness of the diaphragm as much as possible. In order to obtain a thin diaphragm, a thin film type light shading plate becomes useful. Specifically, thickness is preferably 38 μm or less, and most preferably 25 μm or less. However, the light shading plate thinner than 5 μm is not preferable because it cannot be easily handled due to poor handling ability, and is very susceptible to surface defect such as flaw or fold line on the film.

In addition, the resin film substrate preferably has a specified surface irregularity by nano-imprinting process or mat finishing process used shot material. Because of surface irregularity of the resin film substrate, the light shading thin film has surface irregularity, which can serve to reduce direct reflectance of light, that is, lead to a lusterless effect. This is preferable as alight shading plate. It should be noted that, direct reflectance of light of the light shading thin film means a reflectance of light reflected in which reflected light reflects from the surface at an equivalent angle to the incidence angle of the incident light according to the law of reflection.

### (B) Light Shading Thin Film

The light shading thin film to be used in the present invention is a crystalline titanium oxy-carbide film, which has a carbon content of 0.6 or more in C/Ti atomicity ratio and an oxygen content of 0.2 to 0.6 in O/Ti atomicity ratio.

The light shading thin film having a carbon content less than 0.6 in C/Ti atomicity ratio is not preferable because the film becomes gold colored and reflectance in the visible range becomes high. In addition, since the light shading thin film having a carbon content less than 0.6 in C/Ti atomicity ratio shows discoloration due to oxidation of the film when heated at 270° C. in the atmosphere, C/Ti atomicity ratio of the film has to be 0.6 or more to exhibit heat resistance in 270° C.

In the light shading thin film to be used in the present invention, taking adhesion to the resin film substrate into consideration, when an O/Ti atomicity ratio of the thin film is less than 0.2, adhesive strength to the resin film substrate becomes weaker because ratio of metallic bonding nature becomes more dominant whereas ratio of ionic bonding nature becomes less dominant in the bond among atoms constructing the thin film. The thin film having an O/Ti atomicity ratio of 0.2 or more is preferable, because ratio of ionic bonding nature becomes more dominant in the bond among atoms constructing the thin film, and adhesive strength to the resin film substrate becomes stronger due to generation of ionic bonding force between the thin film and the resin film substrate.

The light shading thin film in the present invention may contain, besides the above-described constituent elements of titanium, carbon and oxygen, other metal elements and other elements such as nitrogen, fluorine within a range not to impair the characteristics of the present invention. Introduction of nitrogen into the light shading thin film can be performed by sputtering film deposition by introducing nitrogen gas (addition gas) into the sputtering gas when the light shading thin film is deposited, or alternatively, without using such addition gas, nitrogen can be introduced by containing nitrogen in the target. In addition, introduction of fluorine into the light shading film can be done by containing fluorine in the target.

In addition, the light shading thin film to be used in the present invention may be made by laminating titanium oxy-carbide films each of which has different carbon content and/or oxygen content from each other, so long as the composition of each film is within the range specified by the present invention. In addition, the light shading thin film to be used in the present invention may be the one in which a carbon content and/or an oxygen content is continuously varying along the film thickness direction, so long as an average composition of the whole film is within the range specified by the present invention.

Generally, a bonding between a resin film of an organic substance and a metal film of an inorganic substance is weak. The same is true when the light shading thin film of the present invention is formed on the surface of the resin film. In addition, in order to increase adhesive strength of the film, it is effective to raise the surface temperature of the resin film during film deposition. However, if the film deposition temperature is increased to 130° C. or higher, in some types like PET among the resin films, the temperature exceeds a glass transition point or a decomposition temperature of the resin film. Therefore, the temperature of resin film surface during film deposition is desirably as low as possible, for example, 100° C. or lower. In order to form the light shading thin film of the present invention on the surface of resin film at a temperature of 100° C. or lower with a high adhesive strength, it is absolutely essential to use a titanium oxy-carbide film in which O/Ti atomicity ratio therein is set at 0.2 or more, and further make a crystalline film.

Taking optical characteristics of the thin film in the consideration, the light shading thin film of the present invention having an oxygen content less than 0.2 in O/Ti atomicity ratio is not preferable, because the titanium oxy-carbide film has a metallic color and is inferior in low reflectance and blackness. On the contrary, the thin film having an oxygen content over 0.6 in O/Ti atomicity ratio is also not preferable, because the thin film is inferior in light absorbing function due to too high transmittance and impair low reflectance and light shading performance.

The C/Ti atomicity ratio and O/Ti atomicity ratio in the light shading thin film can be analyzed using, for example, XPS. Since outermost surface of the thin film contains more oxygen, the C/Ti atomicity ratio and O/Ti atomicity ratio in the light shading thin film can be quantified by measuring after removing the layer of several ten nm from the surface by sputtering in vacuum.

In the light shading thin film of the present invention, when film thickness is 260 nm or more in total, an average optical density in a range of wavelength 400 to 800 nm can be made 4.0 or more. However, the total film thickness is more preferably 260 to 500 nm. In order to exhibit complete light shading performance, the total film thickness has to be 260 nm or more, but the total film thickness thicker than 500 nm is not preferable, because of increased production cost due to prolonged time required for deposition the light shading thin film as well as increased material cost for increased materials required for film deposition.

### 2. Method for Forming the Light Shading Thin Film

The light shading thin film to be used in the present invention can be produced, for example, besides by film deposition methods using vacuum process such as sputtering process, vacuum deposition process, CVD process, also by a method in which an ink containing titanium oxy-carbide fine particles dispersed therein is coated. However, among them, production by the sputtering process is preferable not only because the thin film can be formed uniformly on a large area of substrate but also because the thin film can be formed with a high adhesive strength to the substrate.

Crystallinity of the film depends on film deposition conditions, and a high adhesive strength to the film substrate can be exhibited due to crystalline character of the titanium oxy-carbide film.

When the light shading thin film to be used in the film type light shading plate of the present invention is produced by the sputtering process, it is desirable to use a titanium oxy-carbide sintered body target, which has a carbon content of 0.6 or more in C/Ti atomicity ratio and a oxygen content of 0.17 to 0.53 in O/Ti atomicity ratio. The titanium oxy-carbide target is made from a powder mixture of titanium oxide, titanium carbide and titanium metal using hot press method. Titanium oxy-carbide targets having various C/Ti atomicity ratios and O/Ti atomicity ratios can be made by varying compounding ratio of each raw material.

Even when a titanium oxy-carbide target having an O/Ti atomicity ratio less than 0.17 or a titanium carbide target is used, much oxygen can be introduced into the film by using an Ar gas mixed a generous content of O₂ as a sputtering gas, and the light shading thin film within the composition range specified by the present invention can be made. In this case, however, since mixing of a generous amount of oxygen in the sputtering gas sometimes lowers crystallinity of the film, it is required to make the film under a condition within a range of oxygen content where a crystalline film can be obtained. The reason why mixing of a generous amount of oxygen in the sputtering gas lowers crystallinity is that an O₂ gas is ionized by plasma to generate a negatively ionized oxygen ion, which is accelerated by the electric field and bombards the film.

In the light shading plate of the present invention, the light shading thin film is formed in a film type on a resin film substrate, for example, by using a sputtering target of a titanium oxy-carbide sintered body in an argon atmosphere and by direct current magnetron sputtering process. Electric discharge method may be high-frequency discharge, but direct current discharge is preferable because high speed film deposition is possible.

In order to produce the film type light shading plate of the present invention by deposition the titanium oxy-carbide film on a resin film substrate by the sputtering process, for example, a take-up roll sputtering equipment shown in FIG. 3 can be used. This equipment comprises the following steps: roll type resin film substrate 1 is set on wind-off roll 5, and after inside of vacuum chamber 7 of a film deposition room is evacuated by vacuum pump 6 such as turbo-molecular pump, film 1 transported from wind-off roll 5 is taken up by take-up roll 9 after passing through the surface of cooling can roll 8 on the way. In the opposing side of the surface of cooling can roll 8, magnetron cathode 10 is placed, and on this cathode, target 11, which becomes raw material of the film, is fitted. It should be noted that, the film transportation section constructed of wind-off roll 5, cooling can roll 8, take-up roll 9 etc. is isolated from magnetron cathode 10 by partition wall 12.

Firstly, roll type resin film substrate 1 is set on wind-off roll 5, and then inside of vacuum chamber 7 is evacuated by vacuum pump 6 such as turbo-molecular pump. After that, resin film substrate 1 is supplied from wind-off roll 5, and is passed through the surface of cooling can roll 8 on the way, and taken up by take-up roll 9, while electric discharge is made between cooling can roll 8 and cathode 10 to make the titanium oxy-carbide film on resin film substrate 1 which is transported in close contact with the surface of cooling can roll 8. It should be noted that, the resin film substrate is desirably dried by heating at around a temperature of its glass transition temperature before sputtering.

In the sputtering film deposition in the present invention, although gas pressure cannot be unconditionally specified because it varies depending on type of equipment or the like, for example, a method using an Ar gas or an Ar gas mixed an O₂ in an amount of 0.05% or less can be employed as a sputtering gas under a sputtering pressure of 0.2 to 0.8 Pa.

By this method, since sputtering particles arriving at the substrate (resin film) becomes high energy, a crystalline film is formed on a heat resistant resin film substrate, and a strong adhesion is expressed between the thin film and the resin film substrate. When gas pressure during film deposition is lower than 0.2 Pa, argon plasma in the sputtering process becomes unstable due to low gas pressure, quality of the film after film formation becomes poor. In addition, when gas pressure is lower than 0.2 Pa, a mechanism, which recoil argon ions re-sputter a film deposited on the substrate, becomes strong, and tends to disturb formation of a dense film. In addition, when gas pressure during film deposition exceeds 0.8 Pa, crystals in the film are difficult to grow up because energy of sputtered particles arriving at the substrate is low, and particles of metal carbide film becomes coarse. Since film quality becomes not crystalline and highly dense one, adhesive strength to the resin film substrate becomes weaker, and the film tends to come off, and such film cannot be used for a light shading film for applications requiring heat resistance. By this way, the light shading thin film relevant to the present invention having superior crystallinity can be produced stably using a pure Ar gas or an Ar gas mixed (for example, within 0.05%) a small amount of O₂ as a sputtering gas. Mixing of O₂ in 0.1% or more could impair crystallinity of the thin film and is not preferable.

In addition, surface temperature of the resin film substrate during film deposition influences on crystallinity of the metal carbide film. As surface temperature of the resin film during film deposition becomes higher, crystalline orientation of sputtering particles occur more easily resulting in better crystallinity. However, even in a heat resistant resin film, there is a limit in a heating temperature, and even when the most heat resistant polyimide film is used, film deposition should be conducted at a surface temperature of 400° C. or lower. Since in some types of resin film, surface temperature of 130° C. or higher could exceed glass transition point or decomposition temperature thereof, in the case of, for example, PET or the like, surface temperature of the resin film during film deposition is desirably conducted as low as possible, for example, 100° C. or lower. In addition, from the viewpoint of production cost, taking a heating time and heat energy required for heating in consideration, it is effective for cost saving to conduct the film deposition at a temperature as low as possible. Surface temperature of the resin film during film deposition is preferably 90° C. or lower, and more preferably 85° C. or lower.

In addition, during film deposition, the resin film substrate receives spontaneous heating from plasma. By adjusting a gas pressure, input power to target and film transporting speed, it is easy to maintain surface temperature of the resin film substrate during film deposition at a specified temperature by incident thermal electrons from the target to the substrate and thermal radiation from plasma. As gas pressure is lower, as input power is higher, and as film transporting speed is slower, heating effect by spontaneous heating by plasma becomes higher. Even when the resin film substrate is in contact with cooling can roll during film deposition, surface temperature of the resin film substrate becomes far higher temperature than the temperature of the cooling can roll due to effect of the spontaneous heating. However, in the case of a sputtering equipment in which target is placed in the opposing place to the cooling can roll, surface temperature of the resin film substrate by the spontaneous heating greatly depends on temperature of the can roll because the resin film substrate is transported while cooled down by the cooling can roll. Therefore, in order to utilize an effect of the spontaneous heating during film deposition as much as possible, it is effective to set the temperature of the cooling can roll at a relatively high temperature and reduce the transportation speed. Film thickness of the metal carbide film is controlled by film transporting speed during film deposition and input power to target, and as transporting speed decreases and as input power to target increases, the film thickness becomes thicker.

### 3. Structure of the Film Type Light Shading Plate

The film type light shading plate of the present invention has a structure in which a light shading thin film is formed on one or both surfaces of the resin film substrate, characterized in that said light shading thin film is a crystalline titanium oxy-carbide film; a carbon content in the thin film is 0.6 or more in C/Ti atomicity ratio; an oxygen content in the thin film is 0.2 to 0.6 in O/Ti atomicity ratio; a total thickness of the light shading thin films formed on both surfaces is 260 nm or more; an average optical density is 4.0 or more in wavelength 400 to 800 nm.

In addition, preferably the film type light shading plate of the present invention has a structure in which light shading thin films are formed on both surfaces of the resin film, and each of the light shading thin films formed on both surfaces has the same composition and the substantially same film thickness, and also a total thickness of the light shading thin films formed on both surfaces is 260 nm or more.

The reason why a total thickness of the light shading thin films formed on both surfaces of the resin film substrate is specified as 260 nm or more is that light shading performance of the film type light shading plate greatly depends on thickness of the thin film. When the total film thickness is 260 nm or more, light absorption by the film is sufficiently performed and complete light shading performance can be exhibited. The total film thickness less than 260 nm is not preferable because light transmission through the film occurs and the film does not have a role of sufficient light shading function. However, as the thin film becomes thicker, light shading performance becomes better. The thickness exceeding 600 nm leads to increased production cost due to increases in material cost and film deposition time, and also the light shading plate tends to be easily deformed due to increased stress of the thin film. More preferable film thickness is 300 to 500 nm. By controlling a thickness of the titanium oxy-carbide thin film to the above-described level, sufficient light shading performance, low film stress, and reduced production cost can be attained.

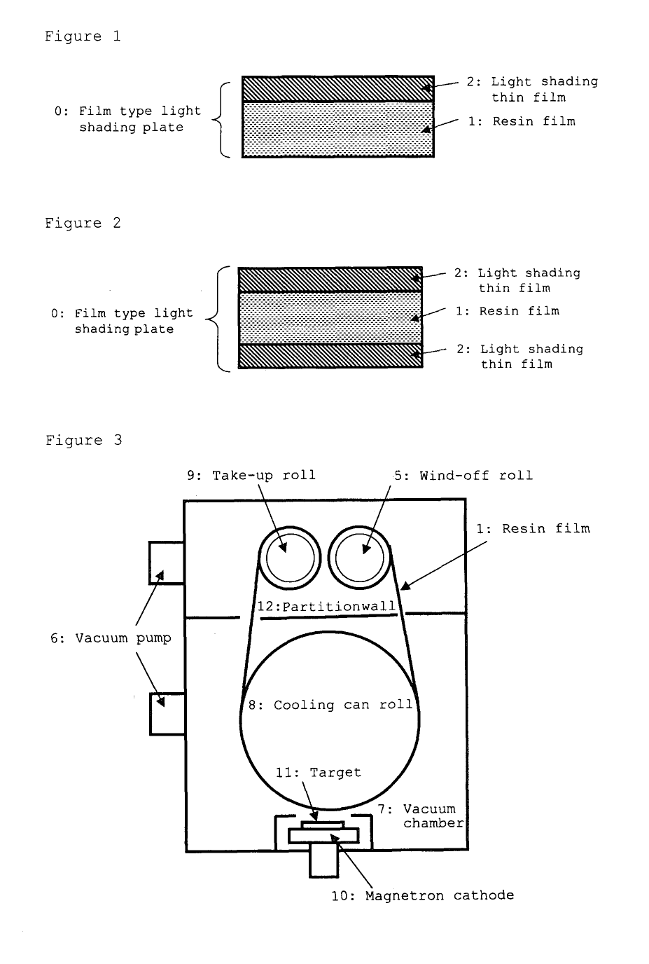

FIG. 1 shows the film type light shading plate of the present invention having a structure in which a light shading thin film is formed on one surface, and FIG. 2 shows the film type light shading plate of the present invention having a structure in which light shading thin films are formed on both surfaces. The above-described titanium oxy-carbide film 2 may be formed on one surface of the resin film substrate as shown in FIG. 1, but preferably it is formed on both surfaces as shown in FIG. 2. When the thin films are formed on both surfaces, it is more preferable that composition and thickness of film on each surface are same, and the light shading plate has a symmetrical structure with the resin film substrate in the center. Since the thin film formed on the substrate gives a stress to the substrate, it becomes a factor of deformation. Deformation by the stress can be seen in the light shading thin film immediately after film deposition, but in particular, the deformation tends to become great and significant when heated at around 155 to 300° C. However, by deposition composition and thickness of the titanium oxy-carbide films formed on both surfaces of the substrate same, and making structure of the light shading plate symmetrical with the substrate in the center as described above, balance of stress can be maintained and a flat film type light shading plate can easily be realized even under heating condition.

As mentioned above, a total thickness of the light shading thin film formed on both surfaces is 260 nm or more. By having the above-described structure, an average optical density in the visible range, that is, in wavelength 400 to 800 nm of 4.0 or more and an average value of direct reflectance on the film surface in wavelength 400 to 800 nm of 39% or less can be obtained. Consequently, a film type light shading plate useful as an optical part can be realized.

Here, optical density is an index to indicate light shading performance, and represented by logarithm with the common logarithm of an inverse number of transmittance in an optical medium, and a value of 4.0 or more means complete light shading performance.

In addition, since the resin film is soft, the light shading plate tends to be deformed by an influence of stress of the thin film formed on the surface. In order to avoid this, it is effective and preferable to form the light shading thin films having the same composition and the same thickness on the both surfaces of the resin film substrate symmetrically.

Surface of the light shading thin film to be used in the film type light shading plate of the present invention has an electrical conductivity because the thin film has the composition and structure as described above. For this reason, in utilizing the light shading plate as a shutter blade, there is an advantageous point that even when blades rub each other at shutter driving, static electricity is hardly generated, and therefore dust is hardly adsorbed. As a level of an electrical conductivity which hardly generates static electricity, a surface resistance of 100 kΩ/□ (should read as kilo ohm per square) or less is sufficient, but in the light shading thin film of the film type light shading plate of the present invention, even with a film thickness of 10 nm, a surface resistance of 3 to 4 kΩ/□ can be realized. Further, with a thickness of 260 nm which exhibits a sufficient light shading performance in single film, a surface resistance of 100 to 200Ω/□ can be realized.

When surface roughness of the resin film substrate is 0.15 to 0.72 μm (arithmetic average height), a direct reflectance on the surface of the light shading thin film in wavelength 400 to 800 nm of 1.5% or less can be obtained. In addition, when surface roughness is 0.35 to 0.72 μm, a direct reflectance becomes 0.8% or less, and a very low reflective film type light shading plate can be realized.

Here, arithmetic average height (Ra) is also referred to as arithmetic average roughness, and means a value obtained by pulling out only a standard length in the direction of its average line from roughness curve, and averaging the total of absolute values of deviations from the average line to the measured curve within this pull out part. As for irregularity on the surface of the substrate, a predetermined surface irregularity can be formed by nano-imprinting process or mat finishing process using shot material. In the case of mat finishing, mat finishing processing used sand as a shot material is common, but shot material is not limited thereto. When a resin film in which a metal light shading film is applied thereon is used as a substrate, it is effective to provide irregularity on the surface of the resin film by the above-described method.

Surface roughness (arithmetic average height Ra) of the light shading thin film is generally close to a surface roughness of the substrate, and when surface roughness of the light shading thin film is 0.15 to 0.70 μm (arithmetic average height), an average value of direct reflectance on the surface of the light shading thin film in wavelength 400 to 800 nm of 1.5% or less can be obtained. In addition, when surface roughness of the light shading thin film is 0.32 to 0.70 μm, a direct reflectance becomes 0.8% or less, and a very low reflective film type light shading plate can be realized.

### 4. Applications of the Film Type Light Shading Plate

The film type light shading plate of the present invention can be utilized as fixed diaphragm or mechanical shutter of digital camera and digital video camera, diaphragm (iris) that allow passage of only a certain light intensity, and further diaphragm blade of a diaphragm device (auto-iris) for adjusting a light intensity for liquid crystal projector by punching out in a particular shape so that edge crack does not occur.

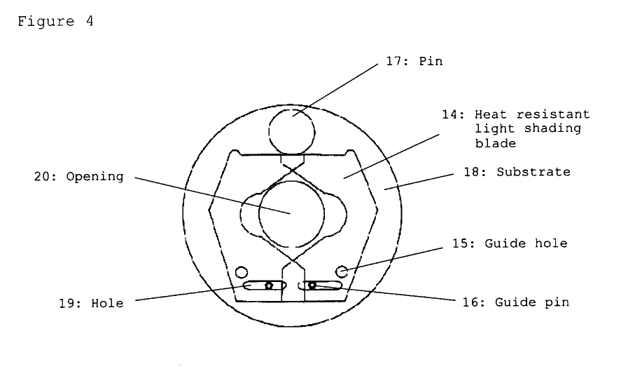

The diaphragm blade of a diaphragm device (auto-iris) for adjusting a light intensity can employ a mechanism allowing an adjustment of light intensity, by using as a plurality of diaphragm blades, making these diaphragm blades variable, and thereby making a diameter of diaphragm opening variable. FIG. 4 is a pattern diagram showing the diaphragms mechanism of a diaphragm device for adjusting a light intensity mounted with black colored light shading blades which are manufactured by punching out the film type light shading plate of the present invention.

In the black colored light shading blade, which is manufactured by using the film type light shading plate of the present invention, a guide hole and a hole for fitting the blade on a base plate are provided, and the base plate has a guide pin engaging with a driving motor and a pin to control a working position of the light shading blade. In addition, there is an opening section where lamp light passes through in the center of the base plate, and the light shading blade can take various shapes depending on structure of the diaphragm device. Since the film type light shading plate using the resin film as a substrate can save its weight, miniaturization of driving member to drive the light shading blades and reduction of electric power consumption are possible.

In the device for adjusting a light intensity for liquid crystal projector, heating by irradiation of lamp light is significant. Therefore, the device for adjusting a light intensity mounting the diaphragm blades, which are manufactured by processing the film type light shading plate of the present invention and have superior heat resistance and light shading performance, is useful. In addition, when lens unit is manufactured by assembling a fixed diaphragm and a mechanical shutter in the reflow process, the fixed diaphragm and the shutter obtained by processing the film type light shading plate of the present invention is very useful, because their characteristics do not change in the heated environment in the reflow process. In the fixed diaphragm in a lens unit of in-vehicle monitor, heating by sun light in midsummer is significant, but the fixed diaphragm manufactured from the film type light shading plate of the present invention is useful because of the same reason.

### EXAMPLES

Next, the present invention will be specifically explained by means of Examples and Comparative Examples, however, the present invention is not limited by these Examples. Film deposition of the light shading thin film was carried out according to the following procedures.

Using the take-up roll sputtering equipment shown in FIG. 3, film deposition of a titanium oxy-carbide film on resin film substrate was carried out. Firstly, the following titanium oxy-carbide target 11 as a raw material of the film was placed on the cathode of the equipment in which magnetron cathode 10 was mounted in the opposing side to the surface of cooling can roll 8. The film transportation section constructed of wind-off roll 5, cooling can roll 8, take-up roll 9 etc. is isolated from magnetron cathode 10 by partition wall 12. After that, roll type resin film substrate 1 was set on wind-off roll 5.

The resin film substrate was sufficiently dried by transporting in close contact with the surface of the can roll heated at 70° C. in vacuum before sputtering.

Next, after evacuating the inside of vacuum chamber 7 by vacuum pump 6 such as turbo-molecular pump, film deposition was carried out by discharging the electricity between cooling can roll 8 and the cathode while resin film substrate 1 is transported in close contact with the cooling can surface. In this time, temperature of the cooling can roll was set at 50° C., and distance between the target and the substrate was set at 50 mm. Ultimate vacuum in the vacuum chamber before film deposition was 2×10⁻⁴ Pa or lower.

Firstly, a titanium oxy-carbide sintered body target was placed on the cathode, from which a titanium oxy-carbide film was made by direct current sputtering process. The titanium oxy-carbide film was made using a pure argon gas (purity: 99.999%) as a sputtering gas at 0.2 Pa. Film deposition was conducted by inputting a direct current power density (direct current input power per unit area of sputtering face of target) of 1.2 to 3.0 W/cm² to target. Thickness of the titanium oxy-carbide film was controlled by controlling the film transporting speed and input power to the target during film deposition. Resin film substrate 1 transported from wind-off roll 5 was taken up by take-up roll 9 through the surface of cooling can roll 8 on the way.

Surface temperature of the resin film substrate during sputtering of the titanium oxy-carbide film was measured by Thermolabel (produced by Nichiyu Giken Kogyo Co., Ltd.) pasted on the film substrate and an infrared thermometer. Measurement by the infrared thermometer was carried out through an observation window made of quartz glass of the take-up roll sputtering equipment.

In addition, evaluations of obtained heat resistant light shading films were carried put by the following methods.

### (Measurement of Film Thickness)

A small piece (50 mm×50 mm) of PES film (produced by Sumitomo Bakelite Co., Ltd., FST-U1340, thickness: 200 μm) having very superior surface smoothness was marked with a permanent marker, then this small piece was pasted up on the roll type resin film to be transported and subjected to film deposition using a heat resistant adhesive tape (produced by Nitto Denko Corp., No. 360UL). After film deposition, the part marked by a magic marker was dissolved with ethanol to remove the film made on the mark. The step of film formed by this way was measured using step/surface roughness/fine shape measurement equipment (produced by KLA-Tencor Japan, Alpha-Step IQ).

### (Composition of Light Shading Film)

Compositions (C/Ti atomicity ratio, O/Ti atomicity ratio) of the obtained films were quantitatively analyzed using XPS (produced by VG Scientific, ESCALAB 220i-XL). It should be noted that, when quantitative analysis is made, composition analysis for inside of a film was carried out after sputter etching a surface layer of 20 to 30 nm of the film.

### (Crystallinity of Light Shading Film)

Crystallinity of a film was evaluated by X-ray diffraction measurement utilized CuK α-ray.

### (Reflectance and Transmittance of Film)

Reflectance and transmittance of film in wavelength 400 to 800 nm were measured using a spectrophotometer (produced by JASCO Corp., V-570), and optical density was calculated from transmittance.

Optical density of an index of light shading performance was converted from transmittance (T) measured by the spectrophotometer according to the following equation. Optical density should be 4 or more, and maximum reflectance value should be less than 10%.

Optical Density=Log(1/T)

### (Surface Roughness)

Surface roughness (arithmetic average height) of the resin film substrate and the light shading thin film formed on the substrate was measured by surface roughness meter (produced by Tokyo Seimitsu Co., Ltd., SURFCOM 570A).

### (Surface Resistance of Film)

Surface resistance of the obtained light shading films was measured by four probe method using a resistance meter (produced by Dia Instruments Co., Ltd., Loresta-EP MCP-T360). When surface resistance is 100 kΩ/□ or less, electrical conductivity was judged as good.

### (Heat Resistance)

Heat resistance of a film was evaluated by checking the occurrence of change in color tone of the film after a heat treatment under the conditions of 270° C. for 1 hour in an atmospheric oven.

### (Adhesive Property)

Adhesive property of the film to the resin film substrate was evaluated according to JIS C0021 (crosscut test), and result was rated as “x” when film came off, and as “o” when film did not come off.

### (Titanium Oxy-Carbide Sintered Body Target)

Titanium oxy-carbide sintered body targets having different compositions with C/Ti atomicity ratios of 0.44 to 1.21 and O/Ti atomicity ratios of 0.10 to 0.61 (6 inches φ×5 mm t, purity: 4N) were used.

The titanium oxy-carbide target was made from powder mixture of titanium oxide, titanium carbide and titanium metal using hot press method. The titanium oxy-carbide targets having various C/Ti atomicity ratios and O/Ti atomicity ratios was able to be made by varying compounding ratio of these raw materials. Composition of the prepared sintered body was quantitatively analyzed by XPS (produced by VG Scientific, ESCALAB 220i-XL), after shaving the surface of fracture cross section of the sintered body by sputtering process.

### Examples 1 to 5, Comparative Examples 1 to 3

Using a polyimide (PI) film having a surface roughness (Ra) of 0.05 μm and a thickness of 25 μm, thin films having specified thicknesses were formed on a non-heated substrate according to the above-described procedures. Titanium oxy-carbide films having the same thickness and the same composition were formed by the same production method on the both surfaces of the film. Surface temperature of the substrate during film deposition was measured by Thermolabel (produced by Nichiyu Giken Kogyo Co., Ltd.) pasted up on the film substrate and a radiation thermometer. Surface temperature of the substrate during film deposition was 80 to 85° C. in any case.

Results of the film type light shading plates thus produced by forming a titanium oxy-carbide film on the polyimide (PI) film substrate are shown in Table 1. The table summarizes compositions and film deposition conditions of the sintered body targets used for film deposition, compositions of the obtained thin films, total of the film thicknesses on each surface, average values of direct reflectance of the thin films in wavelength 400 to 800 nm, average values of optical density in wavelength 400 to 800 nm, roughness (Ra) of the film surface, values of surface resistance, changes in color tone when heated in the atmosphere.

TABLE 1

| | | | | Film deposition conditions | | | | Surface | | | |
|---|---|---|---|---|---|---|---|---|---|---|---|
| | | | | | | | Oxygen | temperature of | | | Total film |
| | Substrate | | | | | Gas | content in | substrate | Film composition | | thickness |
| | | | Surface | Target | | pressure | film | in film | C/Ti | O/Ti | of each |
| | | Thickness | roughness | composition | | in film | deposition | deposition | Atomicity | Atomicity | surfaces |
| | Type | (μm) | Ra (μm) | C/Ti | O/Ti | deposition (Pa) | Ar gas (%) | (° C.) | ratio | ratio | (nm) |
| Comparative | Polyimide | 25 | 0.05 | 0.99 | 0.10 | 0.2 | 0.00 | 80-85 | 1.01 | 0.12 | 260 |
| Example 1 | | | | | | | | | | | |
| Example 1 | | | | 0.99 | 0.17 | | | | 0.99 | 0.21 | |
| Example 2 | | | | 1.01 | 0.41 | | | | 1.02 | 0.45 | |
| Example 3 | | | | 1.03 | 0.53 | | | | 1.04 | 0.58 | |
| Comparative | | | | 0.99 | 0.61 | | | | 0.98 | 0.72 | |
| Example 2 | | | | | | | | | | | |
| Comparative | | | | 0.44 | 0.39 | | | | 0.42 | 0.43 | |
| Example 3 | | | | | | | | | | | |
| Example 4 | | | | 0.60 | 0.39 | | | | 0.62 | 0.43 | |
| Example 5 | | | | 1.21 | 0.42 | | | | 1.23 | 0.45 | |
| Comparative | | | | 0.99 | 0.17 | 0.2 | 0.00 | | 0.99 | 0.21 | 240 |
| Example 4 | | | | | | | | | | | |
| Example 6 | | | | | | | | | | | 360 |
| Comparative | | | | 1.03 | 0.53 | | | | 1.04 | 0.58 | 220 |
| Example 5 | | | | | | | | | | | |
| Example 7 | | | | | | | | | | | 500 |

| | | Average direct | Average | Surface | Surface | Color change | |
|---|---|---|---|---|---|---|---|
| | | reflectance | optical | roughness | resistance | in heating | |
| | | of film in | density in | of film | of surface | test at 270° C. | Adhesive |
| | Crystallinity | wavelength | wavelength | [Ra] | of film | in the | property of |
| | of film | 400 to 800 nm (%) | 400 to 800 nm | (μm) | (Ω/□) | atmosphere | film |
| Comparative | Crystalline | 41.8 | 4.0< | 0.03 | 158 | No change | X |
| Example 1 | film | | | | | | |
| Example 1 | | 38.9 | | 0.03 | 265 | No change | ◯ |
| Example 2 | | 36.4 | | 0.03 | 314 | No change | ◯ |
| Example 3 | | 35.2 | | | 352 | No change | ◯ |
| Comparative | | 33.4 | 3.83 | | 526 | No change | ◯ |
| Example 2 | | | | | | | |
| Comparative | | 44.3 | 4.0< | | 245 | Changed | ◯ |
| Example 3 | | | | | | | |
| Example 4 | | 38.5 | | | 356 | No change | ◯ |
| Example 5 | | 35.1 | | | 452 | No change | ◯ |
| Comparative | | 40.9 | 3.72 | | 323 | No change | ◯ |
| Example 4 | | | | | | | |
| Example 6 | | 38.1 | 4.0< | | 190 | No change | ◯ |
| Comparative | | 40.5 | 3.68 | | 425 | No change | ◯ |
| Example 5 | | | | | | | |
| Example 7 | | 34.5 | 4.0< | | 220 | No change | ◯ |

By reference to Examples 1 to 5 and Comparative Examples 1 to 3 in Table 1, it can be understood that composition of the thin film virtually reflects a composition of the target.

It was confirmed that the films of Examples 1 to 5 were titanium oxy-carbide films having a C/Ti atomicity ratio of 0.62 to 1.23 and an O/Ti atomicity ratio of 0.21 to 0.58, and these films were the light shading thin films of the present invention. From the results of Examples 1 to 5, it can be understood that the light shading thin film of the present invention can be produced using a titanium oxy-carbide sintered body target having a carbon content of 0.6 to 1.21 in C/Ti atomicity ratio and an oxygen content of 0.17 to 0.53 in O/Ti atomicity ratio by sputtering process.

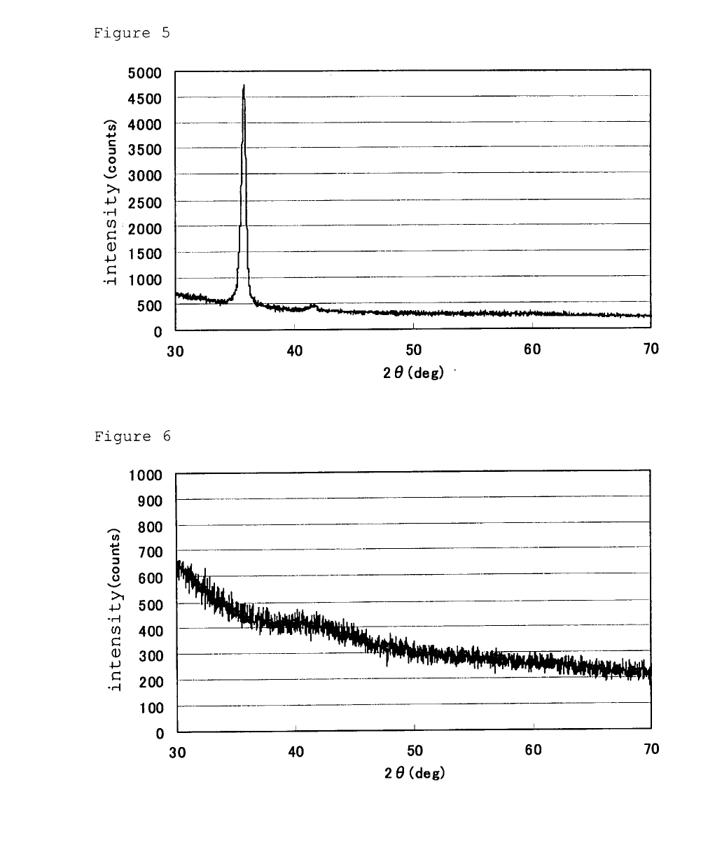

As a result of X-ray diffraction measurement for crystallinity of the film, it was confirmed that all of the films produced in Examples 1 to 5 and Comparative Examples 1 to 3 were the films superior in crystallinity having rock salt type crystal structure. An X-ray diffraction pattern of the film obtained in Example 1 is shown in FIG. 5. A (111) diffraction peak and a (200) diffraction peak attributable to the rock salt type crystal structure were observed at around 35.8 degree and around 41.0 degree, respectively, and no diffraction peaks other than these were observed. Since TiC (JCPDS card 32-1383) and TiO (JCPDS card 08-0117) also have rock salt type crystal structures, titanium oxy-carbide, which is a solid solution of these substances, has the same rock salt type crystal structure.

Surface resistance values in Examples 1 to 5 are 452Ω/□ or less, indicating high electrical conductivities. Consequently, these light shading plates are effective as an optical part because they can inhibit adsorption of dust due to charge of static electricity.

On the contrary, the films produced in Comparative Examples 1 to 2 in Table 1 have O/Ti atomicity ratios deviated from the composition range of the present invention, and the film of Comparative Example 3 has C/Ti atomicity ratio deviated from the composition range specified by the present invention.

Focusing attention on average direct reflectance values of the films in Comparative Example 1, Examples 1 to 3, and Comparative Example 2, as an O/Ti atomicity ratio of the film increases, an average direct reflectance value showed a tendency to decrease. The film of Comparative Example 2 has such a comparatively high O/Ti atomicity ratio as 0.72, but does not have sufficient light shading performance with such an average optical density as less than 4.0. In order to exhibit low reflectivity and sufficient light shading performance, it is important to use a thin film having an O/Ti atomicity ratio of 0.2 to 0.60 as in Examples 1 to 3.

In addition, the film type light shading plate of Comparative Example 3 has an O/Ti atomicity ratio of 0.43, which is within the above-described range, but a C/Ti atomicity ratio of the thin film is 0.42, which is lower and deviated from the range of C/Ti atomicity ratio specified by the present invention. Although such film has an average optical density greater than 4.0 and sufficient light shading performance, but the film expresses gold color and has a very high reflectance. When content of C in the film decreases, a physical property close to TiO film appears, and expresses gold color. Consequently, such film having a high reflectance cannot be used for a surface thin film of an optical part, and a film type light shading plate, which is obtained by being covered with this film, is not useful as an optical part.

Concerning the thin films of Examples 4 to 5, since the compositions of films also is within the range specified by the present invention, they have lower reflectance values in comparison with those of the film type light shading plates of Comparative Examples 1 to 3, as well as optical density values exceeding 4.0, and therefore sufficient light shading property. Consequently, these films can be utilized as a film type light shading plate for an optical part.

### Example 6 and Comparative Example 4

Film type light shading plates were produced in the completely same way as in Example 1 except that the total thicknesses of the titanium oxy-carbide film formed on the film surface was altered to 360 nm (180 nm in each surface) (Example 6) or 240 nm (120 nm in each surface) (Comparative Example 4). These Results are shown in Table 1.

As the surface resistance values in the table show, all of the films indicate the electrical conductivity. Consequently, it can be considered that the problem of dust adsorption due to charge of static electricity hardly occurs.

From the X-ray diffraction measurements of the films of Example 6 and Comparative Example 4, it was found that a film superior in crystallinity had been obtained in any case as in Example 1.

The film type light shading plate of Comparative Example 4, which was produced by forming titanium oxy-carbide films in a total film thickness of 240 nm, had an average optical density less than 4.0 in wavelength 400 to 800 nm, and could not exhibit sufficient light shading performance. On the contrary, the film type light shading plate of Example 6 in which the total film thickness was altered to 360 nm can be said to have sufficient light shading performance because an average optical density exceeds 4.0.

### Example 7 and Comparative Example 5

Film type light shading plates were produced in the completely same way as in Example 3 except that the total film thickness of titanium oxy-carbide film formed on the resin film surface was altered to 500 nm (250 nm in each side) (Example 7) or 220 nm (110 nm in each side) (Comparative Example 5). These results are shown in Table 1.

As the surface resistance values in the table show, all of the films indicate the electrical conductivity. Consequently, it can be considered that the problem of dust adsorption due to charge of static electricity hardly occurs.

From the X-ray diffraction measurements of the thin films of Example 7 and Comparative Example 5, it was found that a film superior in crystallinity had been obtained in any case as in Example 1.

The film type light shading plate of Comparative Example 5, which was produced by forming titanium oxy-carbide films in a total film thickness of 220 nm, had an average optical density of 3.68 in wavelength 400 to 800 nm, and could not exhibit sufficient light shading performance. On the contrary, the film type light shading plate of Example 7 in which the total film thickness was altered to 500 nm can be said to have sufficient light shading performance because an average optical density exceeds 4.0.

### Examples 8 to 12 and Comparative Examples 6 to 8

Film type light shading plates were produced by forming titanium oxy-carbide films in the same way as in Example 1 except that a polyimide film having a surface roughness (Ra) of film surface of 0.35 μm and a thickness of 38 μm was used. The surface roughness of the film was formed in mat finishing by sand blasting. Film thickness in each surface was commonly 200 nm (total film thickness was 400 nm), production method of the film in each surface was also same. These results are shown in Table 2.

As the surface resistance values show, all of the film type light shading plates in Table 2 indicate the electrical conductivity. Consequently, it can be considered that the problem of dust adsorption due to charge of static electricity hardly occurs.

From the X-ray diffraction measurements of the thin films, in any film type light shading plates in Table 2, it was found that a thin film superior in crystallinity had been obtained similarly as in Example 1. In addition, surface roughness (Ra) of the titanium oxy-carbide was 0.32 μm in any case. Consequently, an average value of direct reflectance values in wavelength 400 to 800 nm of the film type light shading plates in Table 2 is smaller in comparison with those of the film type light shading plates of Examples 1 to 11 in which values of surface roughness were small. However, in a comparison of Examples and Comparative Examples in Table 2, there is a difference in their direct reflectance values. Namely, the film type light shading plates in Examples 8 to 12 are the film type light shading plates of the present invention produced used the titanium oxy-carbide film in the composition range of the present invention, but they have a lower average value of average direct reflectance values in wavelength 400 to 800 nm in comparison with the film type light shading plate of Comparative Example 6 used the titanium oxy-carbide film in which O/Ti atomicity ratio is deviated from the composition range of the present invention. Consequently, the film type light shading plates of Examples 8 to 12 are more useful as an optical part. In addition, in this film type light shading plate, the film strongly adheres to the film substrate. Consequently, this plate is particularly useful for an optical part such as shutter due to superior durability. Further, since the film type light shading plates of Examples 8 to 12 have an average optical density of 4.0 or more, they have complete light shading performance.

On the contrary, in Comparative Example 6, since adhesion of the film to the film substrate is weak, this light shading plate cannot be utilized as an optical part from this point of view too. Comparative Example 7 is a film type light shading plate used the titanium oxy-carbide film in which O/Ti atomicity ratio is greater than the composition range of the present invention, but since an average optical density in wavelength 400 to 800 nm is 3.83, the plate does not have sufficient light shading performance. In addition, Comparative Example 8 is a film type light shading plate used the titanium oxy-carbide film in which C/Ti atomicity ratio is less than the composition range of the present invention. An average direct reflectance in wavelength 400 to 800 nm is higher in comparison with those of Examples 8 to 12 produced by using the same resin film substrate, and also exhibited color change in the heating test at 270° C. Consequently, this plate cannot be utilized for an optical part, which is assembled in the reflow process.

TABLE 2

| | | | | Film deposition conditions | | | | Surface | | | |
|---|---|---|---|---|---|---|---|---|---|---|---|
| | | | | | | | Oxygen | temperature of | | | Total film |
| | Substrate | | | | | Gas | content in | substrate | Film composition | | thickness |
| | | | Surface | Target | | pressure | film | in film | C/Ti | O/Ti | of each |
| | | Thickness | roughness | composition | | in film | deposition | deposition | Atomicity | Atomicity | surfaces |
| | Type | (μm) | Ra (μm) | C/Ti | O/Ti | deposition (Pa) | Ar gas (%) | (° C.) | ratio | ratio | (nm) |
| Comparative | Polyimide | 38 | 0.35 | 0.99 | 0.10 | 0.2 | 0.00 | 80-85 | 1.01 | 0.12 | 400 |
| Example 6 | | | | | | | | | | | |
| Example 8 | | | | 0.99 | 0.17 | | | | 0.99 | 0.21 | |
| Example 9 | | | | 1.01 | 0.41 | | | | 1.02 | 0.45 | |
| Example 10 | | | | 1.03 | 0.53 | | | | 1.04 | 0.58 | |
| Comparative | | | | 0.99 | 0.61 | | | | 0.98 | 0.72 | |
| Example 7 | | | | | | | | | | | |
| Comparative | | | | 0.44 | 0.39 | | | | 0.42 | 0.43 | |
| Example 8 | | | | | | | | | | | |
| Example 11 | | | | 0.60 | 0.39 | | | | 0.62 | 0.43 | |
| Example 12 | | | | 1.21 | 0.42 | | | | 1.23 | 0.45 | |

| | | Average direct | Average | Surface | Surface | Color change | |
|---|---|---|---|---|---|---|---|
| | | reflectance | optical | roughness | resistance | in heating | |
| | | of film in | density in | of film | of surface | test at 270° C. | Adhesive |
| | Crystallinity | wavelength | wavelength | [Ra] | of film | in the | property of |
| | of film | 400 to 800 nm (%) | 400 to 800 nm | (μm) | (Ω/□) | atmosphere | film |
| Comparative | Crystalline | 0.83 | 4.0< | 0.32 | 100 | No change | X |
| Example 6 | film | | | | | | |
| Example 8 | | 0.80 | | 0.32 | 165 | No change | ◯ |
| Example 9 | | 0.78 | | 0.32 | 198 | No change | ◯ |
| Example 10 | | 0.76 | | 0.32 | 215 | No change | ◯ |
| Comparative | | 0.74 | 3.83 | 0.32 | 331 | No change | ◯ |
| Example 7 | | | | | | | |
| Comparative | | 1.05 | 4.0< | 0.32 | 156 | Changed | ◯ |
| Example 8 | | | | | | | |
| Example 11 | | 0.79 | | 0.32 | 223 | No change | ◯ |
| Example 12 | | 0.78 | | 0.32 | 285 | No change | ◯ |

### Examples 13 to 17 and Comparative Examples 9 to 11

Film type light shading plates were produced by forming titanium oxy-carbide films in the same way as in Example 1 except that a polyimide (PI) film having a surface roughness (Ra) of film surface of 0.17 μm and a thickness of 50 μm was used. Surface roughness of the film was formed in mat finishing by sand blasting. Film thickness in each surface was commonly 180 nm (total film thickness was 360 nm), production method of the film in each surface was also same. Results are shown in Table 3.

As the surface resistance values show, all of the film type light shading plates in Table 3 indicate the electrical conductivity. Consequently, it can be considered that the problem of dust adsorption due to charge of static electricity hardly occurs.

From the X-ray diffraction measurements of the titanium oxy-carbide films, in any film type light shading plates in Table 3, it was found that a film superior in crystallinity had been obtained similarly as in Example 1. In addition, in the film type light shading plates in Table 3, surface roughness (Ra) of the titanium oxy-carbide film was 0.15 μm in any case. Consequently, in the film type light shading plates in Table 3, average values of direct reflectance in 400 to 800 nm are smaller than those of the film type light shading plates of Examples 1 to 11 in which values of surface roughness were small. However, in a comparison of Examples and Comparative Examples in Table 3, there is a difference in their direct reflectance values. Namely, Examples 13 to 17 are the film type light shading plates of the present invention produced used the titanium oxy-carbide film in the composition range of the present invention, but they have a lower average value of direct reflectance values in wavelength 400 to 800 nm in comparison with the film type light shading plate of Comparative Example 9 used the titanium oxy-carbide film in which O/Ti atomicity ratio is deviated from the composition range of the present invention. Consequently, the film type light shading plates of Examples 13 to 17 are more useful as an optical part. In this film type light shading plate, the film strongly adheres to the resin film substrate. Consequently, this plate is particularly useful for an optical part such as shutter and the like due to superior durability. Since the film type light shading plates of Examples 13 to 17 have an average optical density of 4.0 or more, they have complete light shading performance.

On the contrary, in Comparative Example 9, adhesion of the film to the film substrate is weak, this light shading plate cannot be utilized as an optical part from this point of view too. Comparative Example 10 is a film type light shading plate used the titanium oxy-carbide film in which O/Ti atomicity ratio is greater than the composition range of the present invention, but since an average optical density in wavelength 400 to 800 nm is 3.71, the plate does not have sufficient light shading performance. In addition, Comparative Example 11 is a film type light shading plate used the titanium oxy-carbide film in which C/Ti atomicity ratio is less than the composition range of the present invention. An average direct reflectance in wavelength 400 to 800 nm is higher in comparison with those of Examples 13 to 17 produced by using the same resin film substrate, and also expressed gold color. Consequently, this plate cannot be utilized for an optical part.

TABLE 3

| | | | | Film deposition conditions | | | | Surface | | | |
|---|---|---|---|---|---|---|---|---|---|---|---|
| | | | | | | | Oxygen | temperature of | | | Total film |
| | Substrate | | | | | Gas | content in | substrate | Film composition | | thickness |
| | | | Surface | Target | | pressure | film | in film | C/Ti | O/Ti | of each |
| | | Thickness | roughness | composition | | in film | deposition | deposition | Atomicity | Atomicity | surfaces |
| | Type | (μm) | Ra (μm) | C/Ti | O/Ti | deposition (Pa) | Ar gas (%) | (° C.) | ratio | ratio | (nm) |
| Comparative | Polyimide | 50 | 0.17 | 0.99 | 0.10 | 0.2 | 0.00 | 80-85 | 1.01 | 0.12 | 360 |
| Example 9 | | | | | | | | | | | |
| Example 13 | | | | 0.99 | 0.17 | | | | 0.99 | 0.21 | |
| Example 14 | | | | 1.01 | 0.41 | | | | 1.02 | 0.45 | |
| Example 15 | | | | 1.03 | 0.53 | | | | 1.04 | 0.58 | |
| Comparative | | | | 0.99 | 0.61 | | | | 0.98 | 0.72 | |
| Example 10 | | | | | | | | | | | |
| Comparative | | | | 0.44 | 0.39 | | | | 0.42 | 0.43 | |
| Example 11 | | | | | | | | | | | |
| Example 16 | | | | 0.60 | 0.39 | | | | 0.62 | 0.43 | |
| Example 17 | | | | 1.21 | 0.42 | | | | 1.23 | 0.45 | |

| | | Average direct | Average | Surface | Surface | | |
|---|---|---|---|---|---|---|---|
| | | reflectance | optical | roughness | resistance | | |
| | | of film in | density in | of film | of surface | Adhesive | |
| | Crystallinity | wavelength | wavelength | [Ra] | of film | property of | |
| | of film | 400 to 800 nm (%) | 400 to 800 nm | (μm) | (Ω/□) | film | Remark |
| Comparative | Crystalline | 1.53 | 4.0< | 0.15 | 110 | X | |
| Example 9 | film | | | | | | |
| Example 13 | | 1.49 | | 0.15 | 185 | ◯ | |
| Example 14 | | 1.46 | | 0.15 | 218 | ◯ | |
| Example 15 | | 1.44 | | 0.15 | 245 | ◯ | |
| Comparative | | 1.41 | 3.71 | 0.15 | 368 | ◯ | Light |
| Example 10 | | | | | | | transmission |
| Comparative | | 1.62 | 4.0< | 0.15 | 170 | ◯ | Gold color |
| Example 11 | | | | | | | |
| Example 16 | | 1.47 | | 0.15 | 250 | ◯ | |
| Example 17 | | 1.45 | | 0.15 | 316 | ◯ | |

### Examples 18 to 22 and Comparative Examples 12 to 14

Film type light shading plates were produced by forming titanium oxy-carbide films in the same way as in Example 1 except that a polyethylene naphthalate (PEN) film having a surface roughness (Ra) of film surface of 0.72 μm and a thickness of 100 μm was used. Surface roughness of the film was formed in mat finishing by sand blasting. Film thickness in each surface was commonly 180 nm (total film thickness was 360 nm), production method of the thin film in each surface was also same. Results are shown in Table 4.

As the surface resistance values show, all of the film type light shading plates in Table 4 indicate the electrical conductivity. Consequently, it can be considered that the problem of dust adsorption due to charge of static electricity hardly occurs.

From the X-ray diffraction measurements of the titanium oxy-carbide films, in any film type light shading plates in Table 4, it was found that a film superior in crystallinity had been obtained similarly as in Example 1. In addition, in the film type light shading plates in Table 4, surface roughness (Ra) of the titanium oxy-carbide film was 0.69 μm in any case. Consequently, in the film type light shading plates in Table 4, average values of direct reflectance in 400 to 800 nm are smaller as a whole than those of the film type light shading plates of Examples 1 to 11 in which values of surface roughness were small. However, in a comparison of Examples and Comparative Examples in Table 4, there is a difference in their direct reflectance values. Namely, Examples 18 to 22 are the film type light shading plates of the present invention produced used the titanium oxy-carbide film in the composition range of the present invention has a lower average value of average direct reflectance values in wavelength 400 to 800 nm in comparison with the film type light shading plate of Comparative Example 12 used the titanium oxy-carbide film in which O/Ti atomicity ratio is deviated from the composition range of the present invention. Consequently, the film type light shading plates of Examples 18 to 22 are more useful as an optical part. In this film type light shading plate, the film strongly adheres to the resin film substrate, and this plate is particularly useful for an optical part such as shutter due to superior durability. Since the film type light shading plates of Examples 18 to 22 have an average optical density of 4.0 or more, they have complete light shading performance.

On the contrary, in Comparative Example 12, adhesion of the film to the resin film substrate is weak, this light shading plate cannot be utilized as an optical part from this point of view too. Comparative Example 13 is a film type light shading plate using the titanium oxy-carbide film in which O/Ti atomicity ratio is greater than the composition range of the present invention, but since an average optical density in wavelength 400 to 800 nm is 3.73, the plate does not have sufficient light shading performance. In addition, Comparative Example 14 is a film type light shading plate used the titanium oxy-carbide film in which C/Ti atomicity ratio is less than the composition range of the present invention. An average direct reflectance value in wavelength 400 to 800 nm was higher in comparison with those of Examples 18 to 22 produced by using the same resin film substrate, and also expressed gold color. Consequently, this plate cannot be utilized for an optical part.

TABLE 4

| | | | | Film deposition conditions | | | | Surface | | | |
|---|---|---|---|---|---|---|---|---|---|---|---|
| | | | | | | | Oxygen | temperature of | | | Total film |
| | Substrate | | | | | Gas | content in | substrate | Film composition | | thickness |
| | | | Surface | Target | | pressure | film | in film | C/Ti | O/Ti | of each |
| | | Thickness | roughness | composition | | in film | deposition | deposition | Atomicity | Atomicity | surfaces |
| | Type | (μm) | Ra (μm) | C/Ti | O/Ti | deposition (Pa) | Ar gas (%) | (° C.) | ratio | ratio | (nm) |
| Comparative | PEN | 100 | 0.72 | 0.99 | 0.10 | 0.2 | 0.00 | 80-85 | 1.01 | 0.12 | 360 |
| Example 12 | | | | | | | | | | | |
| Example 18 | | | | 0.99 | 0.17 | | | | 0.99 | 0.21 | |
| Example 19 | | | | 1.01 | 0.41 | | | | 1.02 | 0.45 | |
| Example 20 | | | | 1.03 | 0.53 | | | | 1.04 | 0.58 | |
| Comparative | | | | 0.99 | 0.61 | | | | 0.98 | 0.72 | |
| Example 13 | | | | | | | | | | | |
| Comparative | | | | 0.44 | 0.39 | | | | 0.42 | 0.43 | |
| Example 14 | | | | | | | | | | | |
| Example 21 | | | | 0.60 | 0.39 | | | | 0.62 | 0.43 | |
| Example 22 | | | | 1.21 | 0.42 | | | | 1.23 | 0.45 | |

| | | Average direct | Average | Surface | Surface | | |
|---|---|---|---|---|---|---|---|
| | | reflectance | optical | roughness | resistance | | |
| | | of film in | density in | of film | of surface | Adhesive | |
| | Crystallinity | wavelength | wavelength | [Ra] | of film | property of | |
| | of film | 400 to 800 nm (%) | 400 to 800 nm | (μm) | (Ω/□) | film | Remark |
| Comparative | Crystalline | 0.69 | 4.0< | 0.69 | 115 | X | |
| Example 12 | film | | | | | | |
| Example 18 | | 0.63 | | 0.69 | 191 | ◯ | |
| Example 19 | | 0.62 | | 0.69 | 221 | ◯ | |
| Example 20 | | 0.61 | | 0.69 | 251 | ◯ | |
| Comparative | | 0.59 | 3.73 | 0.69 | 375 | ◯ | Light |
| Example 13 | | | | | | | transmission |
| Comparative | | 0.71 | 4.0< | 0.69 | 179 | ◯ | Gold color |
| Example 14 | | | | | | | |
| Example 21 | | 0.61 | | 0.69 | 261 | ◯ | |
| Example 22 | | 0.60 | | 0.69 | 325 | ◯ | |

### Examples 23 to 25 and Comparative Example 15

In Table 5, film type light shading plates were produced by forming a titanium oxy-carbide film only on one surface in the same way as in Example 1 except that a polyethylene terephthalate (PET) film having a thickness of 188 μm (acryl hard coat of 3 μm thickness had been provided on both surfaces) was used. On the film surface subjected to film deposition, surface irregularity was formed in mat finishing by sand blasting to give a surface roughness (Ra) of 0.20 μm. The titanium oxy-carbide film was made using the same target as in Example 1 under the condition using an argon gas containing around 0.05% of oxygen as a film deposition gas. In comparison with the films of Example 1 which were made in the film deposition gas not containing oxygen, films, which contained extra oxygen content and relatively small carbon content, were obtained, but they were within the composition range of the present invention. Films having a various film thicknesses of 400 nm (Example 23), 310 nm (Example 24), 262 nm (Example 25), and 245 nm (Comparative Comparative Example 15) were produced. Results are shown in Table 5.

As the surface resistance values show, all of the film type light shading plates in Table 5 indicate the electrical conductivity. Consequently, it can be considered that the problem of dust adsorption due to charge of static electricity hardly occurs.

In the thin films of the film type light shading plates in Table 5, a weak diffraction peak was observed in any case, and it was confirmed that although these thin films were inferior in crystallinity in comparison with the thin films of Examples 1 to 22, all of these thin films were crystalline films. Adhesions of these thin films evaluated by the similar conditions were also sufficient due to crystalline films. In addition, in all of the film type light shading plates in Table 5, surface roughness (Ra) of the titanium oxy-carbide film was 0.18 μm in any case. Consequently, in the film type light shading plates in Table 5, average values of direct reflectance in 400 to 800 nm are smaller as a whole than those of the film type light shading plates of Examples 1 to 11 in which values of surface roughness were small. In addition, in the film type light shading plates of Examples 23 to 25, since the total film thickness was within the range of the present invention and average optical density in wavelength 400 to 800 nm were 4.0 or more, these plates showed sufficient light shading performance.

On the contrary, the film type light shading plate of Comparative Example 15 has a thickness of the thin film thinner than the range of the present invention and an average optical density less than 4.0, therefore does not exhibit sufficient light shading performance, and cannot be utilized as an optical part.

Consequently, even when the film is formed on one surface, it can be said that the film thickness has to be 260 nm or more.

TABLE 5

| | | | | Film deposition conditions | | | | Surface | | | |
|---|---|---|---|---|---|---|---|---|---|---|---|
| | | | | | | | Oxygen | temperature of | | | Total film |
| | Substrate | | | | | Gas | content in | substrate | Film composition | | thickness |
| | | | Surface | Target | | pressure | film | in film | C/Ti | O/Ti | of each |
| | | Thickness | roughness | composition | | in film | deposition | deposition | Atomicity | Atomicity | surfaces |
| | Type | (μm) | Ra (μm) | C/Ti | O/Ti | deposition (Pa) | Ar gas (%) | (° C.) | ratio | ratio | (nm) |
| Example 23 | PET | 188 | 0.20 | 0.99 | 0.17 | 0.2 | 0.05 | 80-85 | 0.85 | 0.56 | 400 |
| Example 24 | | | | | | | | | 0.85 | 0.56 | 310 |
| Example 25 | | | | | | | | | 0.85 | 0.56 | 262 |
| Comparative | | | | | | | | | 0.85 | 0.56 | 245 |
| Example 15 | | | | | | | | | | | |

| | | Average direct | Average | Surface | Surface | | |
|---|---|---|---|---|---|---|---|
| | | reflectance | optical | roughness | resistance | | |
| | | of film in | density in | of film | of surface | Adhesive | |
| | Crystallinity | wavelength | wavelength | [Ra] | of film | property of | |
| | of film | 400 to 800 nm (%) | 400 to 800 nm | (μm) | (Ω/□) | film | Remark |
| Example 23 | Crystalline | 1.28 | 4.0< | 0.18 | 71 | ◯ | Film |
| Example 24 | film | 1.25 | | 0.18 | 92 | ◯ | deposition on |
| Example 25 | | 1.23 | | 0.18 | 115 | ◯ | one surface |
| Comparative | | 1.20 | 3.85 | 0.18 | 132 | ◯ | |
| Example 15 | | | | | | | |

### Comparative Example 16

A film type light shading plate having the same structure was produced experimentally under the same conditions as in Example 1 except that a distance between the target and the film substrate was expanded to 200 nm.

The obtained film had a composition with a C/Ti atomicity ratio of 0.92 and an O/Ti atomicity ratio of 0.57, and was found to have an oxygen content more than that of the film of Example 1 but within the composition range of the present invention. An average direct reflectance in wavelength 400 to 800 nm was 37.5% and an average optical density also exceeded 4.0. Change in color tone of the film in the heating test at 270° C. in the atmosphere was not observed.

However, in the evaluation of crystallinity of the thin film by XRD measurement, an X-ray diffraction pattern as shown in FIG. 6 was obtained, indicating that the film had an amorphous structure. As for adhesion of the film evaluated under the same conditions, coming off of the film was observed, and it was found that this could not be utilized as an optical part.

### Comparative Example 17

A film type light shading plate having similar film thickness and film construction to those in the light shading plate of Example 24 was produced under the same production conditions as in Example 24 except that a titanium oxy-carbide sintered body target of having a C/Ti atomicity ratio of 0.99 and an O/Ti atomicity ratio of 0.05 was used and an oxygen content in the sputtering gas in film deposition was altered to 0.10%.

Composition of the obtained film of 310 nm was 0.81 in C/Ti atomicity ratio and 0.58 in O/Ti atomicity ratio, and it is within the composition range specified by the present invention.

However, in the X-ray diffraction measurement of the film, no diffraction peak was observed, and the obtained film was found to have an amorphous structure. It is considered that since oxygen content introduced into the sputtering gas was too much, oxygen ions generated in plasma were accelerated by the electric field between the target and the substrate to bombard the film and disturbed the development of the crystalline film.

In evaluation of adhesion of the obtained film in the similar way, coming off of the film was observed. This was because the film was amorphous film. Such product in which the light shading thin film easily comes off cannot be utilized as an optical part.

### Comparative Example 18

A conventional film type light shading plate (produced by Somar Corp., Somablack), which was obtained by impregnating the black colored fine particles in a PET film, was used as a sample. Optical density and surface resistance values of this film were evaluated without forming a light shading thin film thereon.

As a result, the film with a thickness of 50 μm had an average optical density of 4.0 or more in wavelength 400 to 800 nm, but the film with a thickness of 38 μm had an average optical density of 3.7, and the film with a thickness of 25 μm had an average optical density of 2.5. From these results, it was found that light shading performance became further insufficient as thickness became thinner. Consequently, in the case of the film type light shading plate obtained by impregnating the black colored fine particles in a film, light shading performance was insufficient in comparison with the film type light shading plate of the present invention when thickness was 38 μm or less, and it was found that this plate could not be utilized as an optical part such as shutter, diaphragm.

In addition, since all of these plates do not have electrical conductivity, static electricity is easily generated and problems such as adsorption of dust by electrostatic charge tend to occur.

### Example 26

Weights of the film type light shading films of the present invention were measured. As a result, weights of the light shading plates having a thickness of 50 μm (Examples 13 to 17) were 70 g/m², and weights of the light shading plates having a thickness of 25 μm (Examples 1 to 7) were 37 g/m². In comparison with a light shading plate made of aluminum having the same thickness, a weight of the film type light shading plate of the present invention was around 45%, and it was confirmed that the light shading film of the present invention was obviously more lightweight.

Consequently, when the film type light shading plate of the present invention is used for a shutter blade, it is possible to respond to low-power driving by weight saving and also to contribute to miniaturization of a driving motor. For this reason, it can be said that the film type light shading plate of the present invention is useful for a shutter blade of a high speed shutter.

The film type light shading plate of the present invention can be utilized as a shutter blade material for high speed shutter, which can correspond to low-power driving, and can also contribute miniaturization of driving motor. Miniaturization of a diaphragm device for adjusting a light intensity and a mechanical shutter can be realized by weight saving.

In addition, the film type light shading plate of the present invention can be utilized as a diaphragm blade material of diaphragm device for adjusting a light intensity of liquid crystal projector and a fixed diaphragm material or a shutter blade material which can correspond to assembly in the reflow process.

What is claimed is:

1. A film type light shading plate in which a light shading thin film (B) comprising of a crystalline titanium oxy-carbide film is formed on at least one surface of the resin film substrate (A), characterized in that:
the light shading thin film (B) has an average optical density of 4.0 or more in wavelength 400 to 800 nm by having a carbon content of 0.6 or more as C/Ti atomicity ratio, an oxygen content of 0.2 to 0.6 as O/Ti atomicity ratio, and a thickness of the light shading thin film (B) of 260 nm or more in total.

2. The film type light shading plate according to claim 1, characterized in that the light shading thin film (B) has a film thickness of 260 to 500 nm in total.

3. The film type light shading plate according to claim 1, characterized in that the resin film substrate (A) comprises one or more types of resins selected from polyethylene terephthalate (PET), polycarbonate (PC), polyethylene naphthalate (PEN), polyimide (PI), aramid (PA), polyphenylene sulfide (PPS), or polyether sulfone (PES).

4. The film type light shading plate according to claim 1, characterized in that the resin film substrate (A) is selected from polyimide (PI), aramid (PA), polyphenylene sulfide (PPS), or polyether sulfone (PES) which have heat resistance at temperature of 200° C. or higher.

5. The film type light shading plate according to claim 1, characterized in that a thickness of the resin film substrate (A) is 38 μm or less.

6. The film type light shading plate according to claim 1, characterized in that a thickness of the resin film substrate (A) is 25 μm or less.

7. The film type light shading plate according to claim 1, characterized in that the light shading thin film (B) is formed on the both surfaces of the resin film substrate (A) and both of the light shading thin film (B) have substantially the same composition and the same film thickness.

8. The film type light shading plate according to claim 1, characterized in that the surface of the light shading thin film (B) is electrical conductivity.

9. The film type light shading plate according to claim 1, characterized in that a direct reflectance for light of the surface of the light shading thin film (B) is 39% or less in average in wavelength 400 to 800 nm.

10. The film type light shading plate according to claim 1, characterized in that a surface roughness of the surface of the light shading thin film (B) is 0.15 to 0.70 μm (in arithmetic average height).

11. The film type light shading plate according to claim 9, characterized in that a direct reflectance for light of the surface of the light shading thin film (B) is 1.5% or less in average in wavelength 400 to 800 nm.

12. The film type light shading plate according to claim 10, characterized in that a surface roughness of the surface of the light shading thin film (B) is 0.32 to 0.70 μm (in arithmetic average height).

13. The film type light shading plate according to claim 11, characterized in that a direct reflectance for light of the surface of the light shading thin film (B) is 0.8% or less in average in wavelength 400 to 800 nm.

14. The film type light shading plate according to claim 1, characterized in that film deposition of the light shading thin film (B) is performed on the surface of the resin film substrate (A) by sputtering process while the resin film substrate (A) is set in a roll type in a film delivery section of a sputtering equipment, then taken up from a wind-off section to a take-up section.

15. The film type light shading plate according to claim 1, characterized in that the light shading thin film (B) is formed on the resin film substrate (A) by the sputtering process using a target of titanium oxy-carbide sintered body.

16. The film type light shading plate according to claim 15, characterized in that the target of titanium oxy-carbide sintered body contains 0.6 or more of carbon as C/Ti atomicity ratio and 0.17 to 0.53 of oxygen as O/Ti atomicity ratio.

17. The film type light shading plate according to claim 1, characterized in that surface temperature of the resin film substrate (A) in sputtering is 100° C. or lower.

18. The film type light shading plate according to claim 1, characterized in that the light shading plate has a heat resistance in the high temperature environment at 270° C.

19. A diaphragm made by processing the film type light shading plate according to any one of claims 1 to 18.

20. A diaphragm device for adjusting a light intensity using a blade member obtained by processing the film type light shading plate according to any one of claims 1 to 18.

21. A shutter using a blade member obtained by processing the film type light shading plate according to any one of claims 1 to 18.
